(19) United States
(12) Patent Application Publication
(10) Pub. No.: US 2010/0018678 A1
(43) Pub. Date: Jan. 28, 2010

(54) Vapor Chamber with Boiling-Enhanced Multi-Wick Structure

(75) Inventor: Wing Ming Siu, Hong Kong (HK)

Correspondence Address: EDELL, SHAPIRO & FINNAN, LLC, 1901 RESEARCH BOULEVARD, SUITE 400, ROCKVILLE, MD, 20850, US

(73) Assignee: Convergence Technologies Limited, Hong Kong (HK)

(21) Appl. No.: 12/569,406

(22) Filed: Sep. 29, 2009

Related U.S. Application Data
(63) Continuation of application No. 11/164,429, filed on Nov. 22, 2005, now abandoned.
(60) Provisional application No. 60/632,704, filed on Dec. 1, 2004.

(51) Int. Cl. F28D 15/04; H05K 7/20

(52) U.S. Cl. 165/104.26; 165/104.33

(57) ABSTRACT

A heat transfer device includes a chamber with a condensable fluid with an evaporative region coupled to a heat source. Within the chamber is a boiling-enhanced multi-wick structure.

### CROSS REFERENCE TO RELATED APPLICATIONS

This application is a continuation of U.S. patent application Ser. No. 11/164,429 filed Nov. 22, 2005, entitled “Vapor Chamber with Boiling-Enhanced Multi-Wick Structure,” which claims priority under 35 U.S.C. § 119(e) from U.S. Provisional Patent Application Ser. No. 60/632,704, filed Dec. 1, 2004, and entitled “Vapor Device,” the entire contents of each of which are hereby incorporated by reference.

### BACKGROUND

Cooling or heat removal has been one of the major obstacles of electronic industry. The heat dissipation increases with the scale of integration, the demand of the high performance, and the multi-functional applications. The development of high performance heat transfer devices becomes one of the major development efforts of the industry.

A heat sink is often used for removing the heat from the device or from the system to the ambient. The performance of heat sink is characterized by the thermal resistance with the lower value representing a higher performance level. This thermal resistance generally consists of the heat-spreading resistance within the heat sink and the convective resistance between the heat sink surface and the ambient environment. To minimize the heat-spreading resistance, highly conductive materials, e.g. copper and aluminum are typically used to make the heat sink. However, this solid diffusion mechanism is generally insufficient to meet the higher cooling requirements of newer electronic devices. Thus, more efficient mechanisms have been developed and evaluated, and vapor chamber has been one of those commonly considered mechanism.

Vapor chambers make use of the heatpipe principle in which heat is carried by the evaporated working fluid and is spread by the vapor flow. The vapor eventually condenses over the cool surfaces, and, as a result, the heat is distributed from the evaporation surface (the interface with the heat source) to the condensation surfaces (the cooling surfaces). If the area of the cooling surfaces is much higher than the evaporating surface, the spreading of heat can be achieved effectively since the phase change (liquid-vapor-liquid) mechanism occurs near isothermal conditions.

### SUMMARY

The object of the present invention is to provide a high performance vapor device for heat removal/cooling applications. The overall performance of the vapor device depends on the performance of each components involved in the vapor-liquid cycle (heat spreading mechanism) and the performance of the devices involved on the cooling side (convection mechanism). In order to have high performance, both mechanisms must be addressed.

The vapor-condensate cycle includes condensate flow, boiling, vapor flow, and condensation. In a separate pending patent application, I have disclosed the usage of a Multi-Wick (MW) structure to improve the condensate flow within a vapor chamber (U.S. patent application Ser. No. 10/390,773, which is hereby incorporated by reference). Specifically, the high heat-flux requirement coupled with the size of the vapor chamber creates the illusion of requiring a wicking structure with high wicking-power, but at the same time capable of providing sufficient lift to account for the size of the device. In general, wicking structures that can sustain both high flow-rate and provide large lift require expensive processes. In reality, only the heating (boiling) zone has a high wicking-power requirement, and this wicking-power requirement reduces with increasing distance away from the heating zone. This is because the condensation occurs at a significantly reduced heat-flux, and it is only at the evaporation site where the condensate converges together that must sustain a high condensate flow-rate. Therefore, the wicking structure (referred to as the Multi-Wick structure) can be varied according to the spatial flow rate requirement in order to better balance the forces (capillary force, viscous force, and gravitational force) acting on the liquid.

As this condensate will undergo boiling as it approaches the boiling zone, the object of the present invention is to disclose a Multi-Wick structure adapted for reducing the boiling superheat (the difference between the temperatures of the boiling surface and that of the vapor). Protruded boiling structures have commonly been used in pool boiling for superheat reduction. However, the length scale of the liquid pool is typically larger than that of the protruded structures, and thus the protrusions are generally totally immersed within the liquid pool (liquid-pool boiling). Furthermore, as the liquid near the heating region boils, the neighboring liquid replaces it through a gravity mechanism. In the context of a vapor chamber, this would not only prohibit its operation in anti-gravity orientations, but will also require part of the chamber to be totally flooded with liquid, which may interfere with the vapor and/or condensate flow processes.

In the present invention, boiling enhancement features are adapted into the vapor chamber through a Boiling-Enhanced Multi-Wick (BEMW) structure. With this BEMW structure, the condensate is collected from the condensation sites using a wicking structure with a spatially-varying wicking power, where various boiling enhancement structures are adapted at the heating zone (boiling region) to simultaneously provide wicking power and boiling enhancement. In this manner, the boiling enhancement structure is not totally submerged inside a pool of liquid, and thus could operate in anti-gravity orientations. In addition, this boiling enhancement structure may also act as a 3-D bridging wick, which mayor may not also provide a structural supporting function. In this sense, some aspect of the Boiling-Enhanced Multi-Wick may be considered as a sub-class of the earlier-disclosed Multi-Wick structure.

The boiling enhancement (BE) structure is a protruded wick having a wicking power greater than that at the condensation site. This protruded wick can be in the form of fins so that the liquid can be wicked between the fins towards the tips of the fins. Besides fins, the protruded wick can also be an array of pins. Interlinking structures between fins or pins can also be used to increase the boiling surface-area. Foam/porous structures can also be used in the protruded wick to provide the larger boiling surface-area. In all of these structures, the objective is to provide a heat conduction path from the heating source toward a larger boiling surface, and to saturate this boiling surface (without total immersion) with condensate that is continually supplied by the complex wicking system.

To allow greater flexibility and control in the wicking power, parts of the BEMW structure may be created through a Multi-Layer (ML) structure consisting of layers of materials disposed on top of each other. Each layer does not have to be identical, and the wicking structure may be the result of multiple layers acting in unison. For example, multiple layers of perforated copper sheets may be disposed on top of an un-grooved copper surface to give rise to a groove wicking structure. Similarly, a copper plate may be disposed on top of a grooved copper surface to give rise to a capillary wick. Thus, this Multi-Layer wick may, in general, consists of perforated plates, grooved plates, mesh layers, sintered layer, solid plate, or any combination thereof. Furthermore, the pattern on each layer may have spatially varying properties including varying perforation pattern, varying slits spacing and/or direction, varying porosity, varying pore size, varying mesh size, and any combination thereof.

The vapor chamber can be implemented in different format for different applications. The simplest format is that of a flat heat-spreader where the heat from the heat source is spread to another side, which may be in contact with a fin or another cooling system. Another format is that of a heat sink, where part of the vapor chamber may be in thermal contact with solid fins, or the vapor chamber may consists of base and fin chambers that are functionally connected. In the latter scenario, additional solid fins may be contact with some of the fin chambers to maximize the convecting surfaces. For applications with spatial constraint, the vapor chamber may be in the form of a clip that clips (Vaporclip) onto the printed circuit board (especially for daughter board). The vapor chamber may be further implemented in the form of a casing (Vaporcase) within which electronic devices are functionally disposed. Additionally, the vapor chamber may be implemented as a cabinet within which Vaporcase may be functionally disposed.

As the internal resistance can be highly improved, the convective resistance must be further improved; otherwise the overall performance may still be choked by the convective resistance. Fin structure can be varied from flat fins, pin fins, perforated fins, and porous fins. The interface between the fins and the vapor chamber should be in functional contact. The method of joining the fin structure with the vapor chamber could be any method with or without bonding materials. The method without involving bonding material can be diffusive bonding, welding, or any bonding method known in the arts. The method of bonding with bonding material can be adhesive bonding, soldering, brazing, welding, or any bonding method known in the art. Furthermore, the method can be any combination of them. For better function contact, a “J”-leg may be used at the bonding location of fins for better bonding quality and contact surfaces.

Furthermore, the cooling medium can be air, water, or refrigerant, which depends on applications. For liquid cooling, the heat exchanging portion with the vapor chamber can an open shell type, serial flow type, parallel flow type, or any combination of them.

With different application requirements and constrains, the vapor chamber can be made of metals, plastics, and/or composite materials. The vapor chamber surface may also be in functional contact with different materials, e.g. plastic, metal coating, graphite layer, diamond, carbon-nanotubes, and/or any highly conductive material known in the art.

### BRIEF DESCRIPTION OF THE DRAWINGS

FIG. 1A is a sectional side view of a vapor chamber implemented as a flat plate.

FIG. 1B is a sectional view of the vapor chamber implemented as a flat plate.

FIG. 1C is a schematic view of a boiling enhancement structure integrated with the basic wick.

FIG. 1D is a schematic view of a boiling enhancement structure integrated with the base plate of the vapor chamber.

FIG. 2A is an isometric view of the flat-fin type boiling enhancement structure.

FIG. 2B is an isometric view of the pin-fin type boiling enhancement structure.

FIG. 2C is an isometric view of flat-fin-with-protrusion type boiling enhancement structure.

FIG. 2D is an isometric view of a porous-type boiling enhancement structure.

FIG. 3A is a sectional side view of a flat-plate vapor chamber with extended boiling enhancement structures.

FIG. 3B is a sectional side view of a flat plate vapor chamber with some of the boiling enhancement structures extended.

FIG. 4A is an isometric view of a Multi-Layer implementation of the Boiling-Enhanced Multi-Wick structure.

FIG. 4B is a sectional view of the capillary channels created through the Multi-Layer structure.

FIG. 5A is a sectional view of deep groove structures created through the Multi-Layer structure.

FIG. 5B is a sectional view of irregular-groove structure created through the Multi-Layer structure.

FIG. 6A is an isometric view of Multi-Layer wick with spatially varying slits and perforation pattern.

FIG. 6B is a sectional side view of the Multi-Layer wick with a capillary plane for liquid flow.

FIG. 6C is an isometric view of a plate with stud-like features.

FIG. 7A is a sectional view of a Multi-Layer wick utilizing a mesh structure.

FIG. 7B is a sectional view of a Multi-Layer wick utilizing a sintered layer.

FIG. 8 is a sectional view of a vapor chamber implemented in a heat sink format.

FIG. 9 is an isometric view of a vapor heat sink with solid fins and fin chambers.

FIG. 10 is an isometric view of a vapor heat sink with solid fins in a horizontal orientation.

FIG. 11 is a side view of a vapor heat sink with only solid fins.

FIG. 12 is an isometric view of a vapor heat sink with staggered fin structures.

FIG. 13 is an isometric view of a vapor heat sink with variable-pitch fin structures.

FIG. 14 is a side view of a vapor heat sink with perforated fins.

FIG. 15A is a side view of a vapor heat sink having fins with flow-deflecting structures. FIG. 15B is an isometric view of a fin with flow-deflecting plates.

FIG. 16 is a schematic view showing fins with J-legs.

FIG. 17 is an isometric view of a vapor heat sink with pin fins.

FIG. 18 is an isometric view of a vapor heat sink with a porous-block structure.

FIG. 19A is a sectional side view of a vapor chamber implemented in the form of a case.

FIG. 19B is a schematic view of a heatpipe assembly.

FIG. 20A is an isometric view of a vapor case with fin chambers.

FIG. 20B is an isometric view of a vapor case with solid fins.

FIG. 21 is a sectional side view of a vapor chamber implemented in the form of a cabinet.

FIG. 22 is a side view of a vapor chamber implemented in the form of a clip.

FIG. 23A is an isometric view of an exterior-shell type liquid cooling configuration.

FIG. 23B is an isometric view of a serial-flow liquid cooling configuration.

FIG. 23C is an isometric view of a parallel-flow liquid cooling configuration.

FIG. 23D is an isometric view of a vapor chamber with liquid cooling tubes running into the chamber.

FIG. 23E is the isometric view showing the liquid cooling tubes inside the chamber.

FIG. 24 is an isometric view of a vapor chamber made of polymer/composite materials.

### DETAILED DESCRIPTION

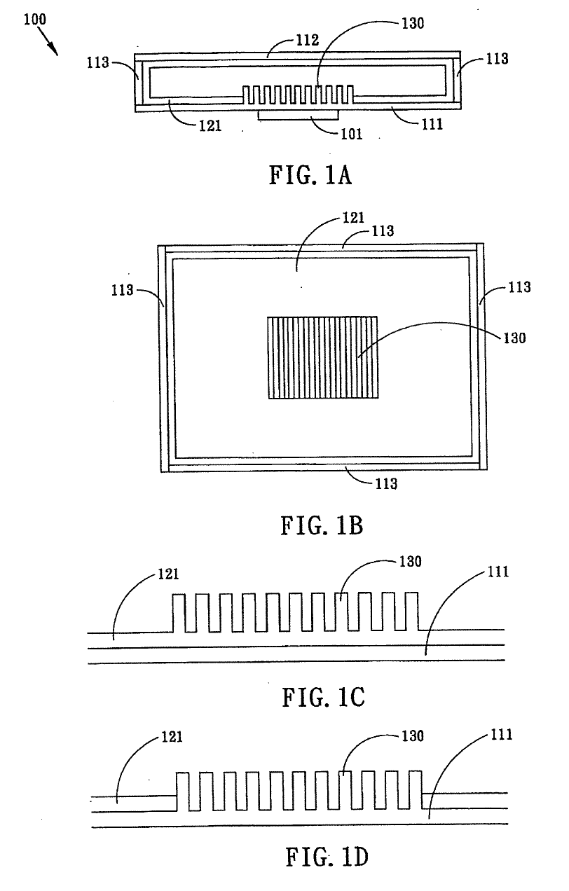

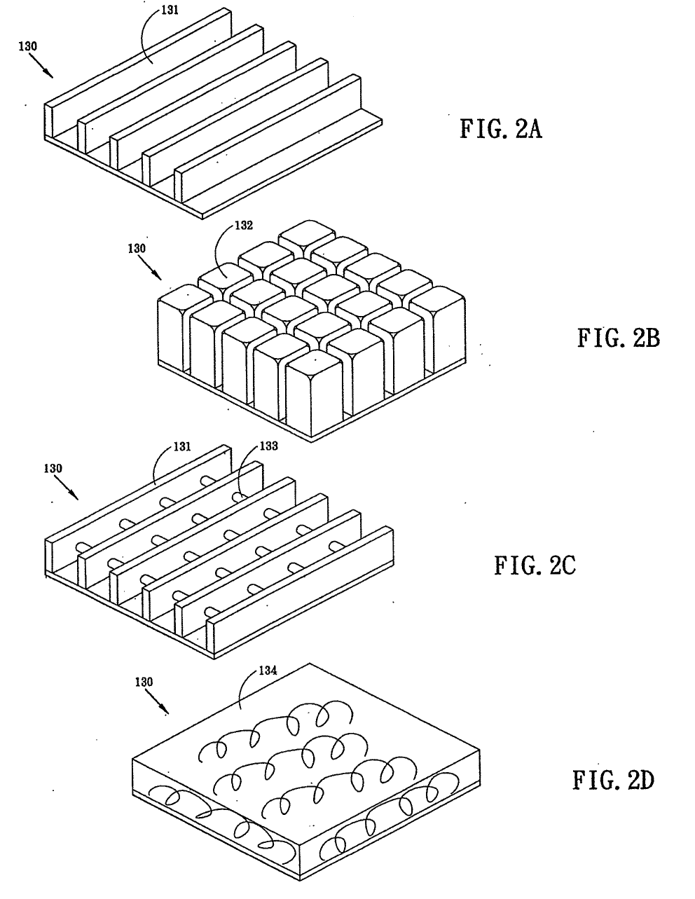

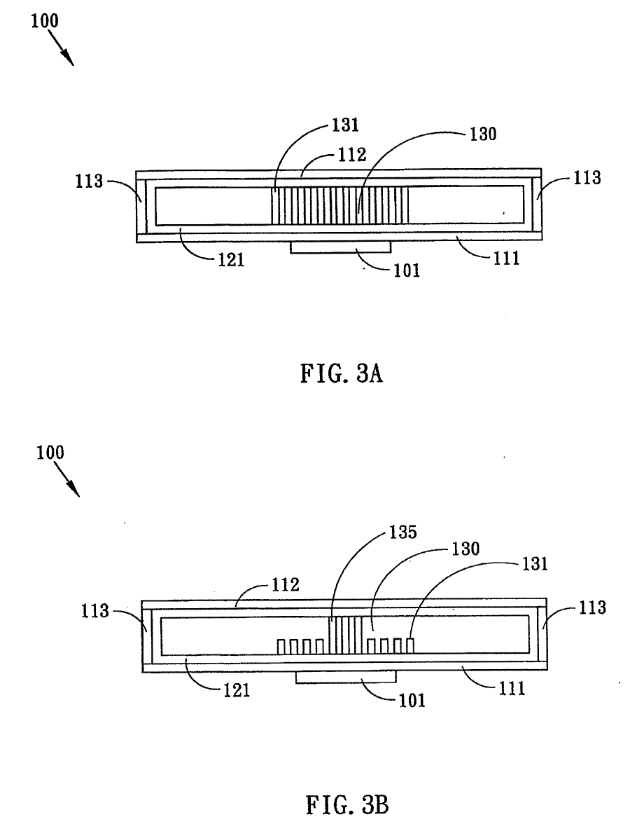

FIG. 1 illustrates an implementation of vapor chamber 100 as a flat plate, which consists of a base plate 111, a top plate 112, four sidewalls 113, a basic wick structure 121, and a boiling enhancement structure 130. When heat is injected from the heat source (electronic device) 101, vapor is generated from the boiling enhancement structure 130. Since the boiling enhancement (BE) structure 130 pulls the liquid in perpendicular to the chamber base 111 (from the basic wick 121 towards the top of the BE structure 130), the boiling surface area is increased such that the increase of massive evaporation and the reduction of boiling heat flux can be achieved. As a result, the boiling superheat can be reduced. This BE structure 130 can be an integrated part of the basic wick 121 (as shown in FIG. 1C) or the integrated part of the base 111 (as shown in FIG. 1D). On the other hand, the BE structure 130 can also be attached as an add-on component. The size of the BE structure 130 can be smaller than, larger than, or the same as the size of the heat source 101. The BE structure 130 can be flat fins 131 (FIG. 2A), pin fins 132 (FIG. 2B), flat fins 131 with protrusions 133 (FIG. 2C), or a thermally-conductive porous/foam structure 134 (FIG. 2D). The BE structure 130 can all be in functional contact 131 with the top plate 112 (FIG. 3A) in order to provide a 3-D bridging wick function (i.e., a bridging wick structure) and allow condensate to directly flow from the top plate 112. Alternatively, as shown in FIG. 3B, only part 130 of the BE structure 131 may be in functional contact 135 with the top plate 112.

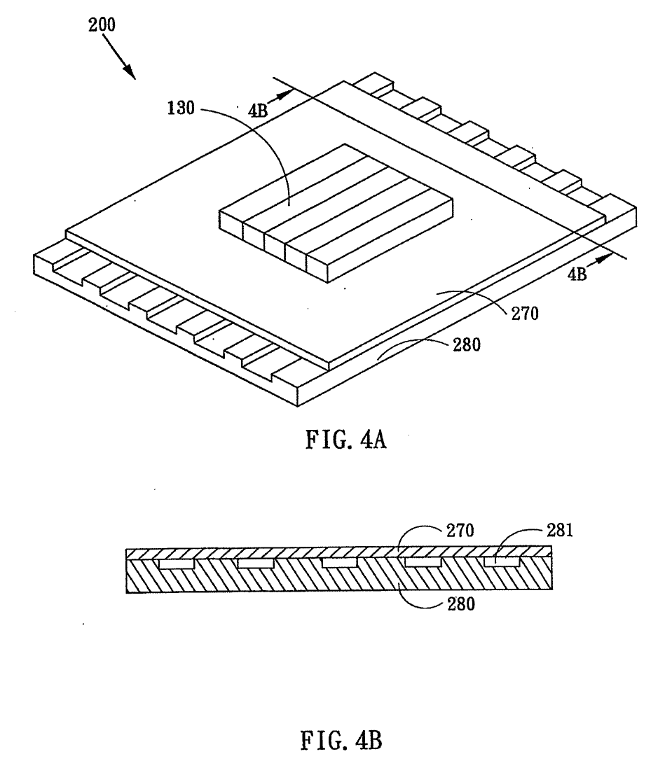

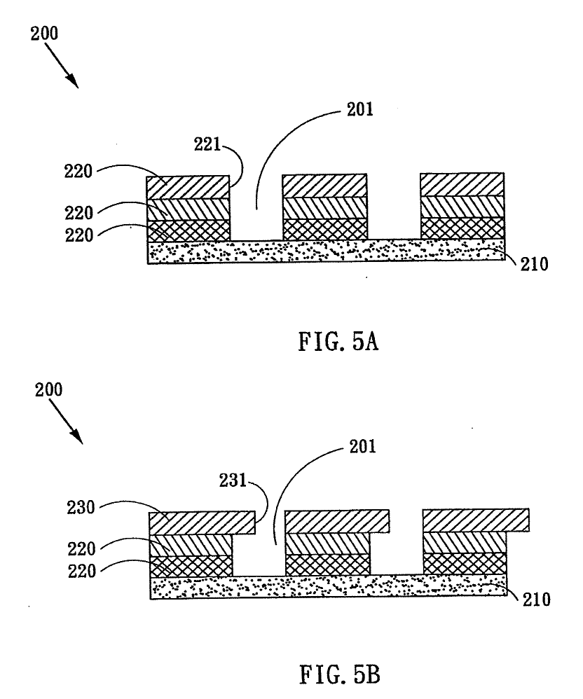

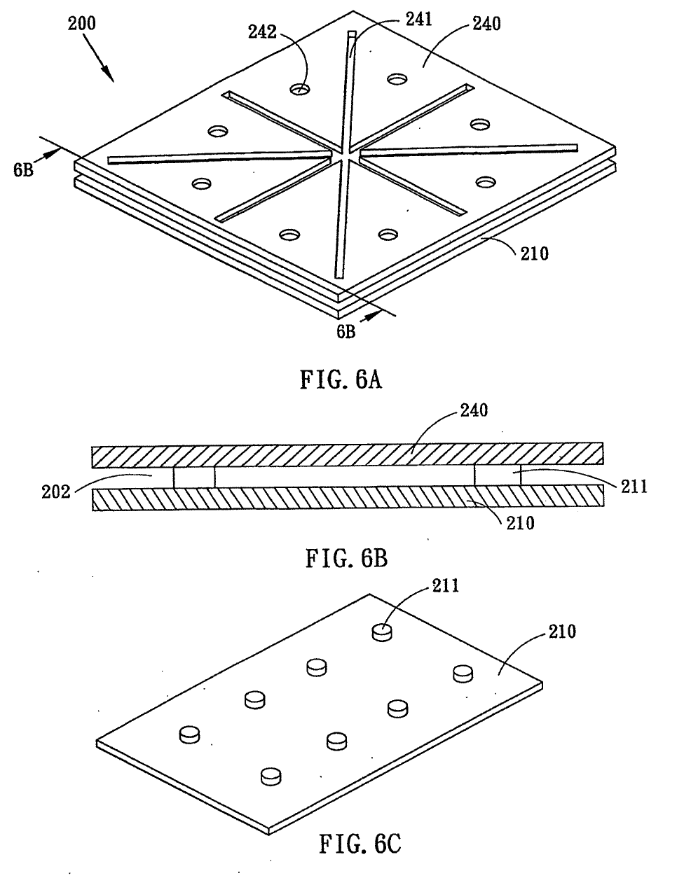

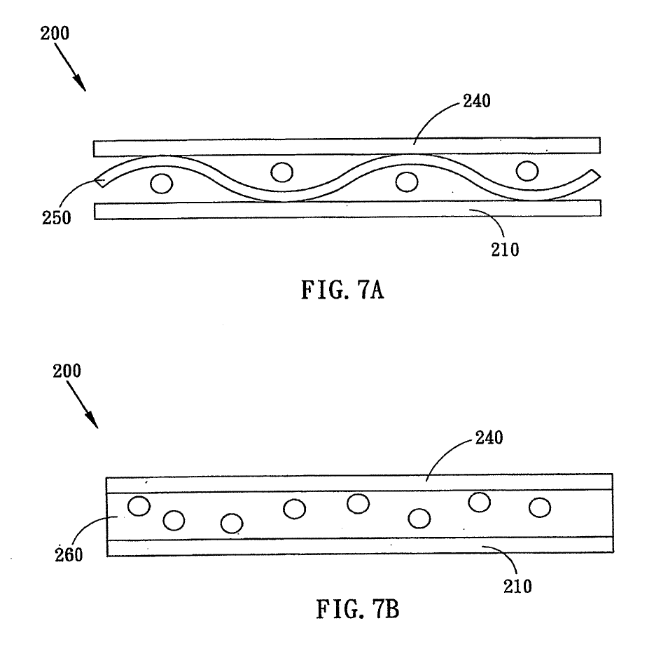

To allow greater flexibility and control in the wicking power, parts of the BEMW structure may be created through a Multi-Layer (ML) structure. FIG. 4 shows one Multi-Layer structure whereby a solid plate 270 is disposed onto a grooved base plate 280 to create capillary channels 281 (FIG. 4B). This solid plate 270 has an opening to accommodate the BE structure 130 (FIG. 4A). By stacking up layers of plates, different capillary channels or grooves can be formed. FIG. 5A shows grooves 201 with large depth-to-width ratio by stacking three plates 220 with slit 221 on top of a plate 210. Similarly, an irregular groove 201 with irregular cross section can be formed by stacking one plate 230 with narrow slit 231 on top of two identical plates 220 with wider slit 221. Referring to FIG. 6, a plate 240 with spatial varying pattern of slits 241 and perforation 242 can be used to create part of the Multi-Wick structure by creating channels 241 to enable a converging liquid flow and allowing the escape of vapor 242. Stud-like feature 211 (FIG. 6C) may also be used in conjunction with stacking-plates 240 to give rise to a thin capillary plane 202 to further provide wicking power control. Besides plates, Multi-Layer structures may also utilize a mesh structure 250 (FIG. 7A) or a sintered layer 260 (FIG. 7b).

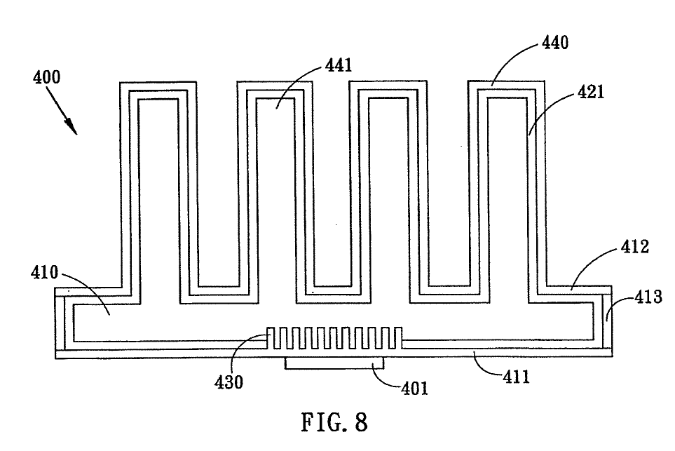

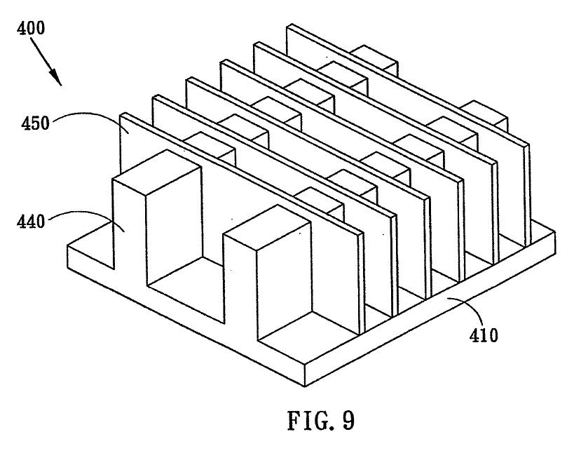

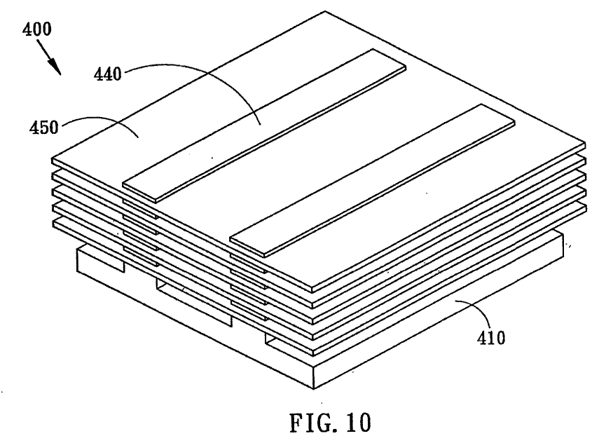

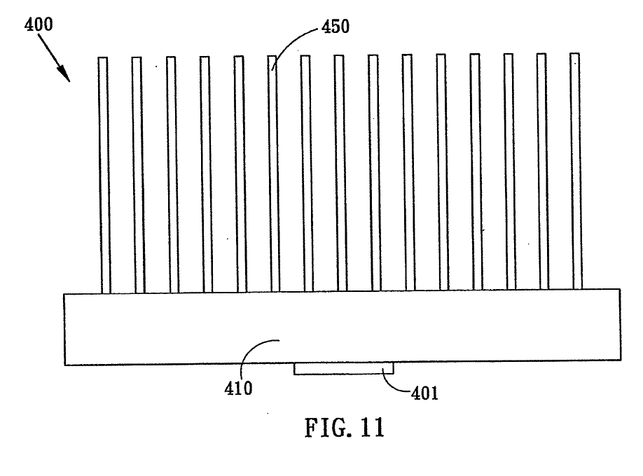

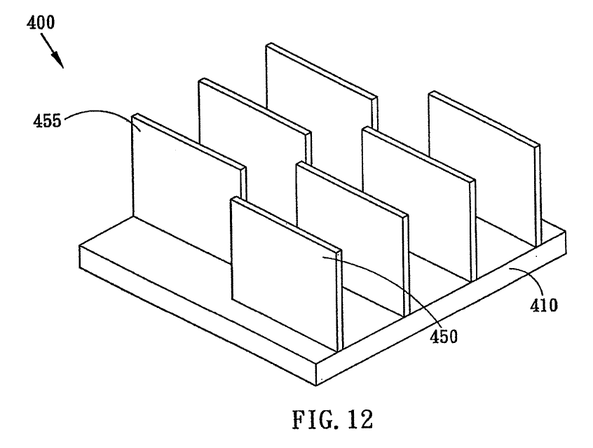

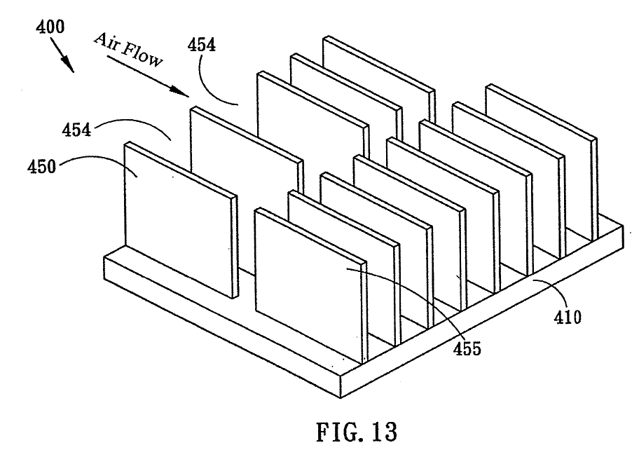

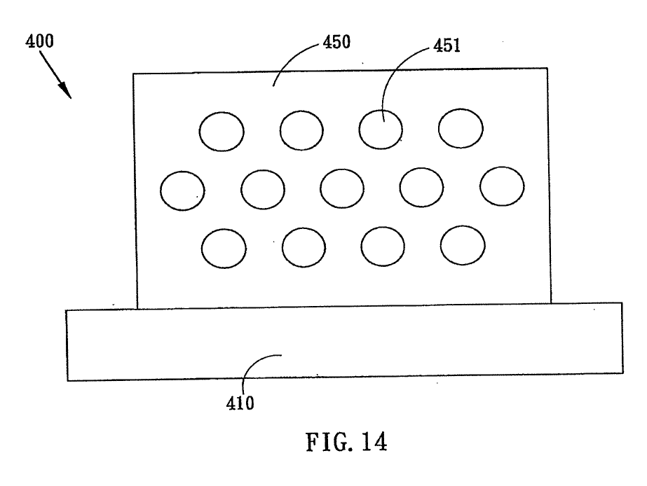

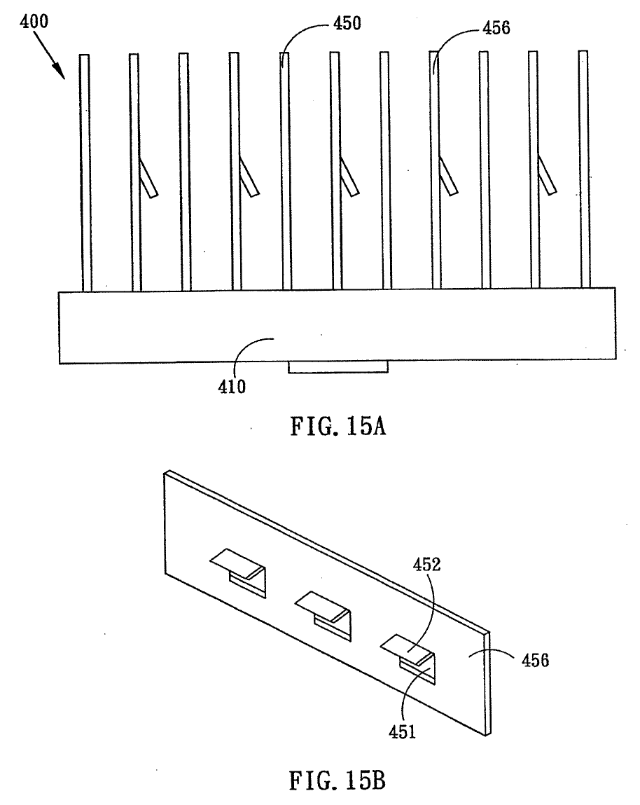

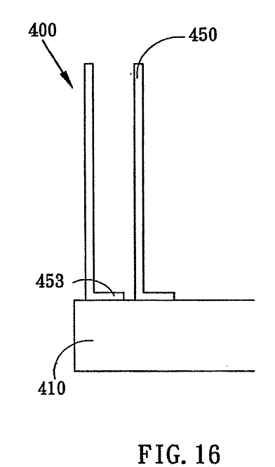

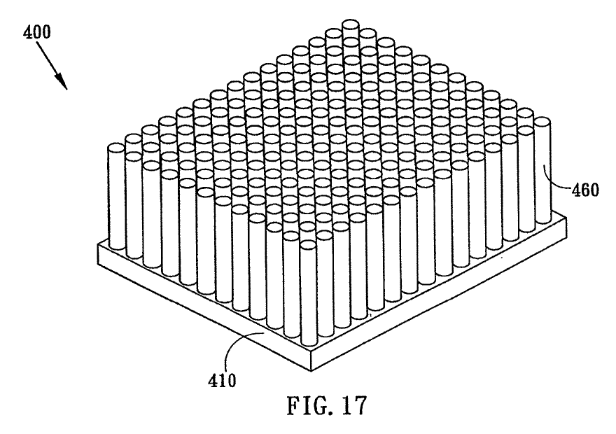

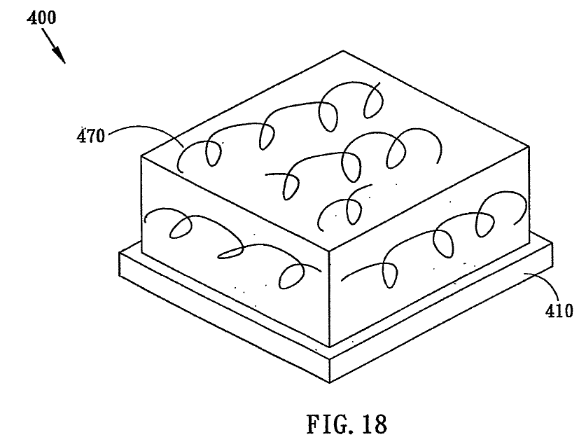

The vapor chamber may be implemented in different format to meet the requirement of different applications. Besides the flat heat spreader format in FIG. 1A, it may also take on the form of a heat-sink 400 (FIG. 8), where the base chamber 410 is in functional contact with the fin chambers 440. Similar to FIG. 1A, a BE structure 430 may be disposed on to a base plate 411, and a basic wick 421 may be disposed onto the remaining surfaces, which together give rise to a Boiling-Enhanced Multi-Wick structure. As the vapor cavity 441 in the fin chambers 440 cannot be too narrow (vapor resistance), there is a limit to the numbers of allowable fin chambers (for a given geometrical constraint). To further increase the total convective surface area, solid fins 450 may be used in conjunction with the fin chambers 440, as shown in FIG. 9. These solid fins may be employed in different orientations (FIG. 10) in order to maximize the heat transfer coefficient. The solid fins may be simple flat plate type 450 (FIG. 11), staggered flat-plate 455 (FIG. 12), with variable pitch 454 (FIG. 13), perforated 451 (FIG. 14), with flow-deflecting structures 452 (FIG. 15) to promote impingement/turbulence effects, with J-legs 453 (FIG. 16) to increase bonding efficiency, pin fins 460 (FIG. 17), and/or as a porous block 470 (FIG. 18).

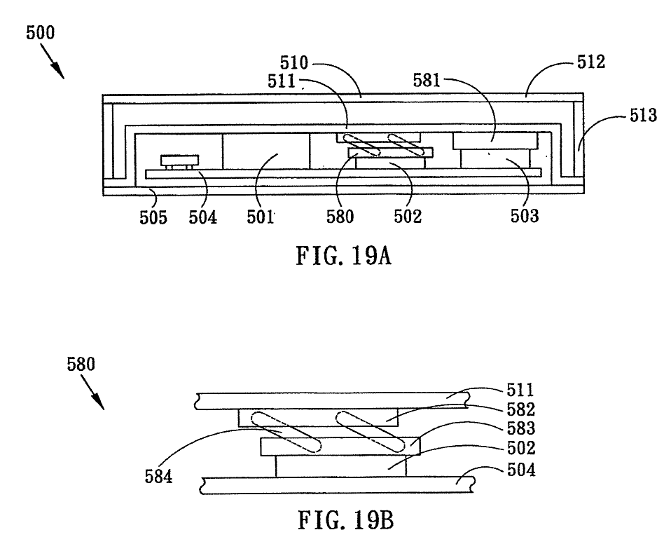

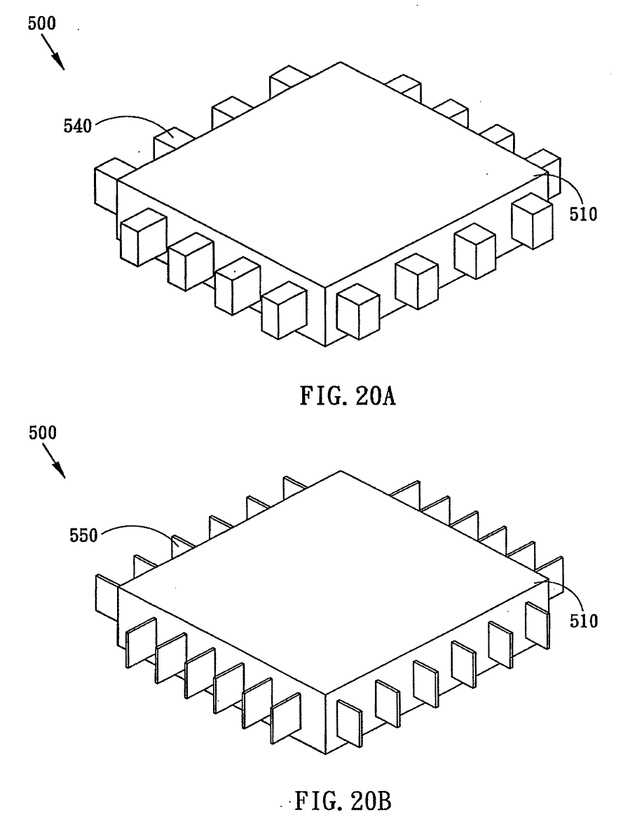

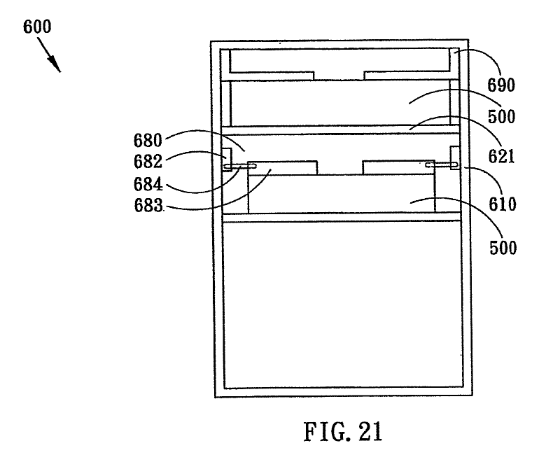

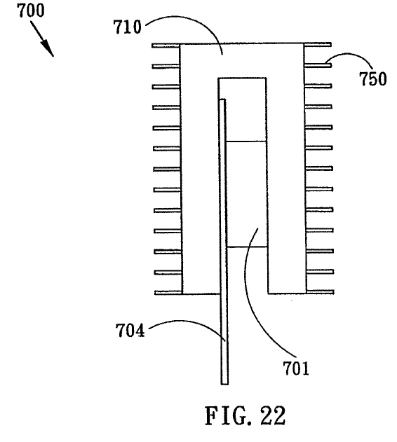

Besides the heat sink format 400 (FIG. 8), the vapor chamber can be implemented in the form of a case 500 (FIG. 19 and 20), cabinet 600 (FIG. 21) or a clip 700 (FIG. 22). For the case format 500 (FIG. 19A), there could be multiple electronic components 501 502 503 which needs to be cooled and which may be mounted on a printed circuit board 504. The printed circuit board can be functionally disposed on the base 505 of the case 500. The components may be in direct contact 501 with the base plate 511 of the vapor chamber 510, or be in functional contact through another conducting medium 581, or through another heatpipe assembly 580 (FIG. 19B) that may consist of conducting medium 582, 583 functionally coupled with heatpipes 584. All these coupling surfaces (inter-component-coupling or intra-coupling) may involve thermal interfacial material for ensure good functional contact. Furthermore, the fins for the case format may be fin chambers 540 (FIG. 20A) or solid elements 550 (FIG. 20B). Applying the same application between the component and the case to the next scale of system (the case and the cabinet), a cabinet format can be adapted. As shown in FIG. 21, a vapor cases 500, may be functionally disposed onto the rack 621 of a vapor cabinet 600. Functional coupling with the vapor chamber of the case 610 can be accomplished through another vapor chamber 690. A Solid-block-heatpipe assembly 680 may also be used for this functional coupling, where this assembly 680 may consist of solid blocks 682 683 and at heatpipes 684. Finally, the vapor chamber may take the form of a clip 700 (FIG. 22), in which the chamber (clip format) 710 may be in functional contact with the electronic component 701 and/or the printed circuit board 704. Fins 750 may be in functional contact with the chamber 710 to increase the total convecting surface area.

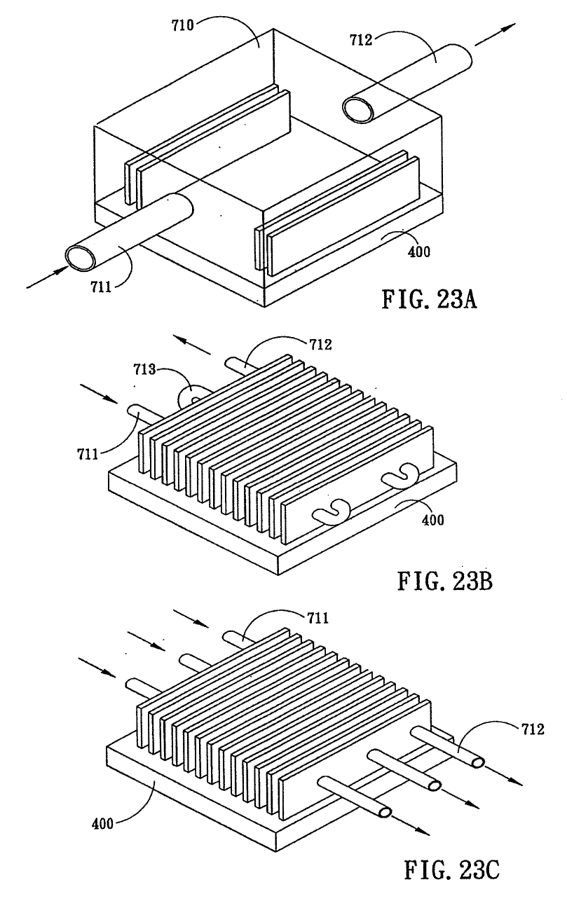

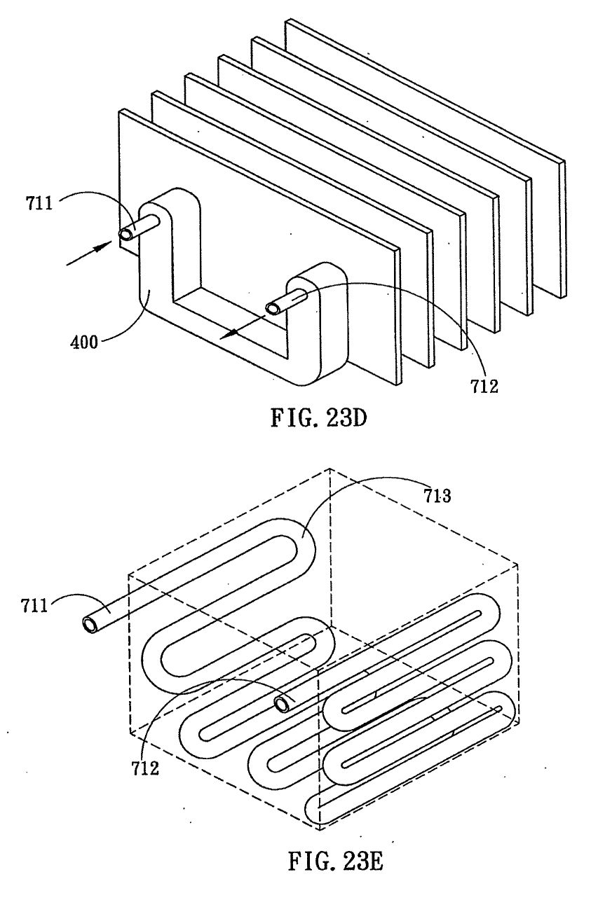

Besides air, the cooling medium may be a liquid (such as water or refrigerant) which may be remove heat from the vapor chamber 400 in the format of an exterior shell 710 (FIG. 23A) with inlet 711 and outlet 712, or in the format of liquid-cooled tubes that are functionally contacting the fin structures in series (FIG. 23B) or in parallel (FIG. 23C). Alternatively, in FIG. 23D, the liquid-cooled pipe 713 may run into the vapor chamber 400 for direct removal of heat from within the vapor chamber 400. The surface of the pipe 713 (FIG. 23E) may have wicks, such as grooves for better condensed liquid flow back to the evaporation region.

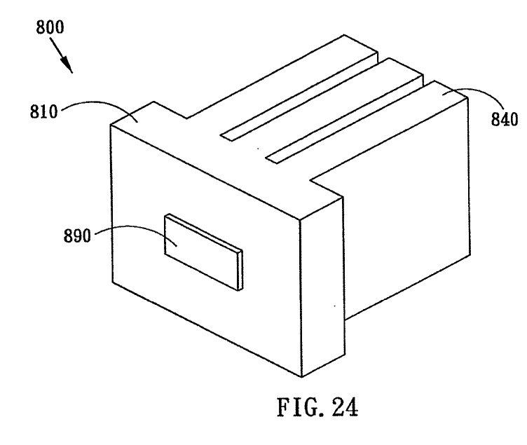

The vapor chamber 800 (FIG. 24) can be made of metallic material, polymers and/or composite materials. if the heat flux from the heat source is high, a highly conductive material 890 should be introduced as a separated part of the base chamber 810. If polymer is used, a metallic coating or any other material in the arts should be disposed in the internal surface for vapor and/or air leakage protection. To further improve the heat transfer performance of the vapor chamber, an external coating of highly conductive material could be applied to the base and/or fin chambers (not shown). This coating may be graphite, metallic, diamond, carbon-nanotube, or any material known in the arts.

A number of embodiments have been described. Nevertheless, it will be understood that various modifications may be made without departing from the spirit and scope. Accordingly, other embodiments are within the scope of the following claims.

What is claimed is:

1. A heat transfer device, comprising:
at least one chamber containing a condensable fluid, the at least one chamber including an evaporation region configured to be coupled to a heat source for vaporizing the condensable fluid, the vaporized condensable fluid collecting as condensate on surfaces within the at least one chamber; and
a boiling-enhanced multi-wick structure comprising a plurality of interoperable wick structures disposed within the at least one chamber for facilitating flow of the condensate toward the evaporation region and reducing an associated boiling superheat.

2. The heat transfer device of claim 1, wherein the at least one chamber includes a condensation site, and wherein the boiling-enhanced multi-wick structure includes a wick at the condensation site and a boiling-enhanced wick at the evaporation region that has a higher wicking power factor than the wick at the condensation site.

3. The heat transfer device of claim 2, wherein the boiling-enhanced wick at the evaporation region includes at least one of: fins, pins, interlinking structures between fins, interlinking structures between pins, foam, and porous structure.

4. The heat transfer device of claim 3, wherein the porous structure includes mesh.

5. The heat transfer device of claim 1, where at least part of the boiling-enhanced multi-wick structure comprises a multi-layer structure comprising at least one of: a plate, a mesh, at least one groove in a surface of the at least one chamber, a sintered layer, and a porous layer.

6. The heat transfer device of claim 1, wherein the boiling-enhanced multi-wick structure has a spatially varying wick structure that varies in accordance with the condensate's spatial flow requirements as the condensate travels toward the evaporation region.

7. The heat transfer device of claim 6, wherein the boiling-enhanced multi-wick structure includes at least one of: at least one fin, at least one pin, a plate, a mesh, a groove in a surface of at least one chamber, a powder wick, and a foam wick.

8. The heat transfer device of claim 6, wherein the spatially varying wick structure includes a spatially varying quantity of wicking structure.

9. The heat transfer device of claim 1, wherein the boiling-enhanced multi-wick structure includes at least one bridging wick structure interoperably connecting portions of the boiling-enhanced multi-wick structure to facilitate flow of the condensate between the portions of the boiling-enhanced multi-wick structure.

10. The heat transfer device of claim 9, wherein the bridging wick structure comprises at least one of: fins, pins, interlinking structures between fins, interlinking structures between pins, foam, mesh, and porous structure; and wherein a proximity of at least a portion of the bridging wick structure to at least a part of the condensation surface enables the functional return of condensate.

11. The heat transfer device of claim 9, wherein the bridging wick structure comprises an internal support structure for the at least one chamber.

12. The heat transfer device of claim 1, wherein the boiling-enhanced multi-wick structure includes a wick structure with varying porosity.

13. The heat transfer device of claim 1, wherein some part of at least one chamber is in functional contact with at least one fin.

14. The heat transfer device of claim 13, wherein the at least one fin includes at least one opening through which air can flow.

15. The heat transfer device of claim 1, wherein at least one chamber includes a base chamber and a fin chamber.

16. The heat transfer device of claim 15, wherein at least one fin is in functional contact with the fin chamber.

17. The heat transfer device of claim 1, wherein the at least one chamber has a substantially clip configuration.

18. The heat transfer device of claim 1, wherein the at least one chamber forms a part of a casing enclosure.

19. The heat transfer device of claim 1, wherein the at least one chamber forms a part of a cabinet enclosure.

20. The heat transfer device of claim 1, wherein the at least one chamber is in functional contact with a cooling liquid.

21. The heat transfer device of claim 1, wherein part of the at least one chamber is constructed out of at least one of: metal, plastic, metal coated plastic, graphite, diamond and carbon-nanotubes.

22. The heat transfer device of claim 1, wherein the at least one chamber includes an internal support structure to prevent collapse of the at least one chamber.

23. A method for transferring heat from a heat source, the method comprising:
receiving heat in a heat device from the heat source, the heat device comprising at least one chamber containing a condensable fluid, the at least one chamber including an evaporation region configured to be coupled to the heat source; and a boiling-enhanced multi-wick structure comprising a plurality of interoperable wick structures disposed within the at least one chamber for facilitating flow of the condensate toward the evaporation region and reducing an associated boiling superheat; and
vaporizing the condensable fluid in the at least one chamber, the vaporized condensable fluid collecting as condensate on surfaces within the at least one chamber.
